(19) United States
(12) Patent Application Publication
(10) Pub. No.: US 2023/0036320 A1
(43) Pub. Date: Feb. 2, 2023

(54) APPARATUS FOR REDUCING CURRENT HYSTERESIS AND METHOD THEREOF

(71) Applicants: HYUNDAI MOTOR COMPANY, Seoul (KR); KIA CORPORATION, Seoul (KR)

(72) Inventors: Byeong Eun Cho, Yongin-si (KR); Jun Yeol Paek, Seoul (KR)

(21) Appl. No.: 17/711,267

(22) Filed: Apr. 1, 2022

(30) Foreign Application Priority Data
Jul. 28, 2021 (KR) 10-2021-0099393

(51) Int. Cl. H02J 7/00

(52) U.S. Cl. CPC H02J 7/0047; H02J 7/007

(57) ABSTRACT

A current hysteresis reducing apparatus includes a processor configured to calculate a current hysteresis value of a fuel cell, to determine whether to operate a low current avoidance driving mode by using the current hysteresis value, and to enter the low current avoidance driving mode to avoid a low-current driving area, and a storage configured to store data and algorithms driven by the processor.

### CROSS REFERENCE TO RELATED APPLICATIONS

This application claims priority to and benefits of Korean Patent Application No. 10-2021-0099393, filed in the Korean Intellectual Property Office on Jul. 28, 2021, the entire contents of which are incorporated herein by reference.

### BACKGROUND

### (a) Field

The present disclosure relates to a current hysteresis reducing apparatus and a method thereof, and more particularly, to a technique for performing a current density lower limit control when a current hysteresis value is greater than a reference value.

### (b) Description of the Related Art

Electrode degradation due to high potential exposure is reduced by limiting a voltage rise of a stack during high-potential a low-current driving area of a hydrogen fuel cell vehicle. This may increase a service life of a fuel cell stack. In this case, an average cell voltage of a fuel cell is limited not to exceed a reference value (e.g. 0.850 V), and a voltage is controlled by suppressing a voltage rise through reduction of cathode air flow and charging a battery through a bi-directional high voltage DC-DC converter (BHDC).

When a cell current gradually increases (forward) and when it decreases in reverse from a highest current (backward), a voltage difference at a same current is regarded as a current hysteresis value of a cell. In general, moisture required for hydration of a fuel cell film/electrode is supplied by water produced by many electrochemical reactions in a high current, and thus a voltage in a forward direction is higher than a voltage in a backward direction.

The current hysteresis value is related to distribution of water inside the fuel cell. A large hysteresis value indicates that the distribution of the water inside the cell is not uniform, and in a vehicle environment in which a required current amount dynamically changes, a current deviation may occur in the fuel cell, which may result in performance deterioration and electrode degradation.

Conventionally, a voltage rise of a hydrogen fuel cell stack is limited based on a voltage, and thus since a number of electrochemical reactions is small, an imbalance in distribution of water within a cell may occur even in a current where an average cell voltage maintains performance of a reference value (0.850 V) depending on stack components and MEA specifications. In addition, when limiting a voltage through low air flow control, it is not related to an increase in generated water because a voltage rise is suppressed by artificial thinning of the air. Accordingly, in order to solve these problems, control based on current density is required.

The above information disclosed in this Background section is only for enhancement of understanding of the background of the disclosure, and therefore, it may contain information that does not form the prior art that is already known in this country to a person of ordinary skill in the art.

### SUMMARY

An exemplary embodiment of the present disclosure has been made in an effort to provide a current hysteresis reducing apparatus and a method thereof, capable of maintaining a stack current generation above a reference level when a current hysteresis value is greater than or equal to a reference value, to avoid a low-current driving area where there is little water produced by electrochemical reactions and to reduce a current hysteresis value by improving distribution through increasing a water content inside a cell, thereby improving performance and durability.

The technical objects of the present disclosure are not limited to the objects mentioned above, and other technical objects not mentioned can be clearly understood by those skilled in the art from the description of the claims.

An exemplary embodiment of the present disclosure provides a current hysteresis reducing apparatus including a processor configured to calculate a current hysteresis value of a fuel cell, to determine whether to operate a low current avoidance driving mode by using the current hysteresis value, and to enter the low current avoidance driving mode to avoid a low-current driving area, and a storage configured to store data and algorithms driven by the processor.

In an exemplary embodiment, the processor, when entering the low current avoidance driving mode, may avoid a low-current driving area where there is little water produced by electrochemical reactions by generating a stack current to be greater than or equal to a reference value.

In an exemplary embodiment, the processor may control a stack current to be generated to be greater than or equal to lower limit current density when entering the low current avoidance driving mode.

In an exemplary embodiment, the processor, when entering the low current avoidance driving mode, may use an excess of a required current amount of the stack current for charging a battery through bidirectional high voltage DC/DC converter (BHDC) in a voltage upper limit control method.

In an exemplary embodiment, the processor may determine current density sensed while driving a vehicle based on a predetermined reference value.

In an exemplary embodiment, the processor may distinguish a current increasing situation and a current decreasing situation by using an amount of change in current with time when the current density is the predetermined reference value.

In an exemplary embodiment, the processor may calculate an accumulated average voltage by accumulating an average cell voltage in the current increasing situation, and may calculate an accumulated average voltage by accumulating an average cell voltage in the current decreasing situation.

In an exemplary embodiment, the processor may calculate the current hysteresis value by using the accumulated average voltage in the current increasing situation and the accumulated average voltage in the current decreasing situation.

In an exemplary embodiment, the processor may calculate the current hysteresis value by subtracting the accumulated average voltage in the current increasing condition from the accumulated average voltage in the current decreasing condition.

In an exemplary embodiment, the processor may initialize the accumulated average voltage in the current decreasing situation and the accumulated average voltage in the current increasing situation when the vehicle ends driving, and may calculate the current hysteresis value by re-calculating the accumulated average voltage in the current decreasing situation and the accumulated average voltage in the current increasing situation when the vehicle starts driving.

In an exemplary embodiment, the processor may compare the current hysteresis value with a predetermined reference value, and when the current hysteresis value exceeds the predetermined reference value, may determine a state requiring reduction of current hysteresis.

In an exemplary embodiment, the processor, when the current hysteresis value may exceed the predetermined reference value, enters the low current avoidance driving mode.

In an exemplary embodiment, the processor when the current hysteresis value exceeds the predetermined reference value, may change from a voltage upper limit control method to a current lower limit control method to perform it, and when the current hysteresis value is smaller than or equal to a predetermined reference value, changes from the current lower limit control method to the voltage upper limit control method.

An exemplary embodiment of the present disclosure provides a current hysteresis reducing method including calculating a current hysteresis value of a fuel cell, determining whether to operate a low current avoidance driving mode by using the current hysteresis value, and entering the low current avoidance driving mode to avoid a low-current driving area.

In an exemplary embodiment, the entering of the low current avoidance driving mode may include, when entering the low current avoidance driving mode, avoiding a low-current driving area where there is little water produced by electrochemical reactions by generating a stack current to be greater than or equal to a reference value.

In an exemplary embodiment, the entering of the low current avoidance driving mode may include, controlling a stack current to be generated to be greater than or equal to lower limit current density when entering the low current avoidance driving mode.

In an exemplary embodiment, the entering of the low current avoidance driving mode may further include, when entering the low current avoidance driving mode, using an excess of a required current amount of the stack current for charging a battery through bidirectional high voltage DC/DC converter (BHDC) in a voltage upper limit control method.

In an exemplary embodiment, the calculating of the current hysteresis value of the fuel cell may include determining current density sensed while driving a vehicle based on a predetermined reference value, and distinguishing a current increasing situation and a current decreasing situation by using an amount of change in current with time when the current density is the predetermined reference value.

In an exemplary embodiment, the calculating of the current hysteresis value of the fuel cell may further include calculating an accumulated average voltage by accumulating an average cell voltage in the current increasing situation, and calculating an accumulated average voltage by accumulating an average cell voltage in the current decreasing situation.

In an exemplary embodiment, the calculating of the current hysteresis value of the fuel cell may further include calculating the current hysteresis value by using the accumulated average voltage in the current increasing situation and the accumulated average voltage in the current decreasing situation.

According to the present technique, it is possible to provide a current hysteresis reducing apparatus and a method thereof, capable of maintaining a stack current generation above a reference level when a current hysteresis value is greater than or equal to a reference value, to avoid a low-current driving area where there is little water produced by electrochemical reactions and to reduce a current hysteresis value by improving distribution through increasing a water content inside a cell, thereby improving performance and durability.

In addition, various effects that can be directly or indirectly identified through this document may be provided.

### BRIEF DESCRIPTION OF THE FIGURES

FIG. 1 illustrates a block diagram showing a configuration of a vehicle system including a current hysteresis reducing apparatus according to an exemplary embodiment of the present disclosure.

FIG. 2 illustrates a block diagram showing a detailed configuration of a current hysteresis reducing apparatus according to an exemplary embodiment of the present disclosure.

FIG. 3 illustrates a current hysteresis reducing method according to an exemplary embodiment of the present disclosure.

FIG. 4 illustrates a flowchart showing a method for calculating a current hysteresis value according to an embodiment of the present disclosure.

FIG. 5 illustrates a flowchart showing a method for determining a current hysteresis value according to an embodiment of the present disclosure.

FIG. 6 illustrates a low current avoidance driving method according to an exemplary embodiment of the present disclosure.

FIG. 7 illustrates a current hysteresis measurement graph according to an exemplary embodiment of the present disclosure.

FIG. 8 illustrates a performance comparison graph for a forward section according to an exemplary embodiment of the present disclosure.

FIG. 9 illustrates a simulated current profile during actual driving of a vehicle according to an exemplary embodiment of the present disclosure.

FIG. 10 illustrates voltage distribution during simulation of actual driving of a vehicle according to an exemplary embodiment of the present disclosure.

FIG. 11 illustrates a computing system according to an exemplary embodiment of the present disclosure.

### DETAILED DESCRIPTION

Hereinafter, some exemplary embodiments of the present disclosure will be described in detail with reference to exemplary drawings. It should be noted that in adding reference numerals to constituent elements of each drawing, the same constituent elements have the same reference numerals as possible even though they are indicated on different drawings. In addition, in describing exemplary embodiments of the present disclosure, when it is determined that detailed descriptions of related well-known configurations or functions interfere with understanding of the exemplary embodiments of the present disclosure, the detailed descriptions thereof will be omitted.

In describing constituent elements according to an exemplary embodiment of the present disclosure, terms such as first, second, A, B, (a), and (b) may be used. These terms are only for distinguishing the constituent elements from other constituent elements, and the nature, sequences, or orders of the constituent elements are not limited by the terms. In addition, all terms used herein including technical scientific terms have the same meanings as those which are generally understood by those skilled in the technical field to which the present disclosure pertains (those skilled in the art) unless they are differently defined. Terms defined in a generally used dictionary shall be construed to have meanings matching those in the context of a related art, and shall not be construed to have idealized or excessively formal meanings unless they are clearly defined in the present specification.

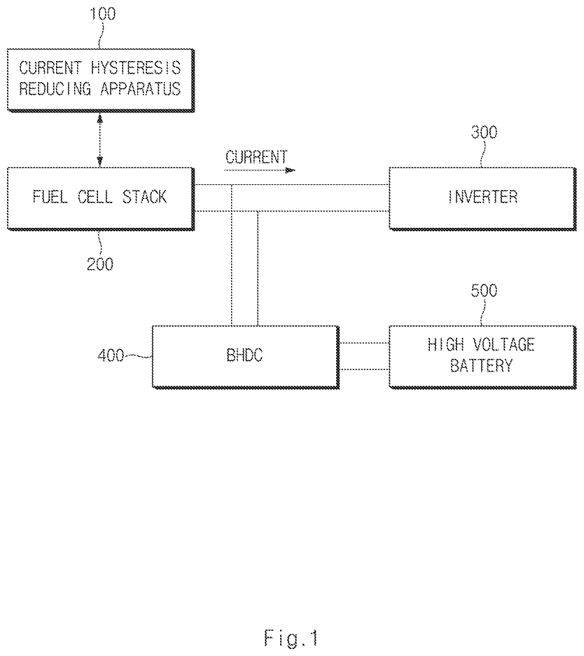

Hereinafter, exemplary embodiments of the present disclosure will be described in detail with reference to FIG. 1 to FIG. 11.

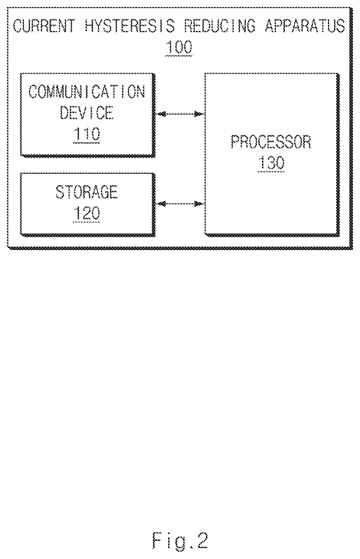

FIG. 1 illustrates a block diagram showing a configuration of a vehicle system including a current hysteresis reducing apparatus according to an exemplary embodiment of the present disclosure, and FIG. 2 illustrates a block diagram showing a detailed configuration of a current hysteresis reducing apparatus according to an exemplary embodiment of the present disclosure.

Referring to FIG. 1, the vehicle system according to the exemplary embodiment of the present disclosure includes a current hysteresis reducing apparatus 100, a fuel cell stack 200 that serves as a main power source (power source) of a vehicle, an inverter 300 connected to a main bus terminal that is an output side of a high voltage battery 500, a bidirectional high voltage DC/DC converter (BHDC) 400 connected to the high voltage battery 500 to enable output control of the high voltage battery 500, and the high voltage battery 500 serving as an auxiliary power source for the vehicle.

The current hysteresis reducing apparatus 100 according to the exemplary embodiment of the present disclosure may be implemented inside a vehicle. In this case, the current hysteresis reducing apparatus 100 may be integrally formed with internal control units of the vehicle, or may be implemented as a separate device to be connected to control units of the vehicle by a separate connection means.

The current hysteresis reducing apparatus 100 may be implemented as a control device for an eco-friendly vehicle using a fuel cell.

The current hysteresis reducing apparatus 100 may calculate a current hysteresis value of a fuel cell, may determine whether to operate a low current avoidance driving mode by using the current hysteresis value, and may enter the low current avoidance driving mode to avoid a low-current driving area.

Referring to FIG. 2, the current hysteresis reducing apparatus 100 may include a communication device 110, a storage 120, and a processor 130.

The communication device 110 is a hardware device implemented with various electronic circuits to transmit and receive signals through a wireless or wired connection, and may transmit and receive information based on in-vehicle devices and in-vehicle network communication techniques. As an example, the in-vehicle network communication techniques may include controller area network (CAN) communication, local interconnect network (LIN) communication, flex-ray communication, and the like.

The storage 120 may store data and/or algorithms required for the processor 130 to operate, and the like. For example, the storage 120 may store an algorithm for calculating current hysteresis, an algorithm for determining whether to execute the low current avoidance driving mode, an algorithm for executing the low current avoidance driving mode, and the like.

As an example, the storage 120 may store an accumulated average voltage V_{b} in a backward situation, an accumulated average voltage V_{f} in a forward situation, the calculated current hysteresis, a reference value α for determining the current hysteresis, a reference value β for determining a required current amount, a threshold value for determining current density, and the like.

The storage 120 may include a storage medium of at least one type among memories of types such as a flash memory, a hard disk, a micro, a card (e.g., a secure digital (SD) card or an extreme digital (XD) card), a random access memory (RAM), a static RAM (SRAM), a read-only memory (ROM), a programmable ROM (PROM), an electrically erasable PROM (EEPROM), a magnetic memory (MRAM), a magnetic disk, and an optical disk.

The processor 130 may be electrically connected to the communication device 110, the storage 120, and the like, may electrically control each component, and may be an electrical circuit that executes software commands, thereby performing various data processing and calculations described below.

The processor 130 may process a signal transferred between components of the current hysteresis reducing apparatus 100, and may perform overall control such that each of the components can perform its function normally.

The processor 130 may be implemented in the form of hardware, software, or a combination of hardware and software, or may be implemented as microprocessor, and may be, e.g., an electronic control unit (ECU), a micro controller unit (MCU), or other subcontrollers mounted in the vehicle.

The processor 130 may calculate a current hysteresis value of the fuel cell, may determine whether the current hysteresis value exceeds a predetermined reference value, and may determine whether to operate the low current avoidance driving mode.

The processor 130 may determine the current density sensed while driving the vehicle based on a predetermined reference value. In this case, the predetermined reference value may be preset by an experimental value, and may be, e.g., 0.32 A/cm².

In addition, the processor 130 may compare the current density with the predetermined reference value, and when the current density matches the predetermined reference value, may calculate an amount of change in current with time, and may distinguish a current increasing situation (forward) and a decreasing situation (backward) depending on the amount of change in current with time.

That is, when the amount of change in current with time exceeds 0, the processor 130 may determine it as the current increasing situation, and when the amount of change in current with time is smaller than or equal to 0, the processor 130 may determine it as the current decreasing situation.

The processor 130 may calculate an accumulated average voltage by accumulating an average cell voltage in the current increasing situation, and the accumulated average voltage by accumulating an average cell voltage in the current decreasing situation, and then may calculate a current hysteresis value by using the accumulated average voltage in the current increasing situation and the accumulated average voltage in the current decreasing situation. More specifically, the processor 130 may calculate the current hysteresis value by subtracting the accumulated average voltage in the current increasing condition from the accumulated average voltage in the current decreasing condition.

The processor 130 may initialize the accumulated average voltage in the current decreasing situation and the accumulated average voltage in the current increasing situation calculated during driving of the vehicle when the vehicle ends driving, and may calculate the current hysteresis value by re-calculating the accumulated average voltage in the current decreasing situation and the accumulated average voltage in the current increasing situation when the vehicle starts driving, to perform update. Accordingly, the current hysteresis value can be updated in real time.

The processor 130 may compare the current hysteresis value with a predetermined reference value, and when the current hysteresis value exceeds the predetermined reference value, may enter a state requiring reduction of current hysteresis, i.e., the low current avoidance driving mode. In this case, the reference value may be determined in advance by experimental values.

In addition, the processor 130 may change from a voltage upper limit control method to a current lower limit control method in the low current avoidance driving mode, and when the current hysteresis value is smaller than or equal to a predetermined reference value, may change from the current lower limit control method to the voltage upper limit control method.

When entering the low current avoidance driving mode, the processor 130 may enter the low current avoidance driving mode to avoid a low-current driving area where there is little water produced by electrochemical reactions by generating a stack current to be greater than or equal to a reference value, and may control the stack current to be generated to be greater than or equal to lower limit current density when entering the low current avoidance driving mode.

In addition, the processor 130 may use an excess of a required current amount of the stack current when entering the low current avoidance driving mode for charging the battery through the BHDC 400 in a voltage upper limit control method.

As such, according to the present disclosure, when the current hysteresis value is greater than or equal to the reference value, it is possible to avoid the driving in the low-current area where there is little water produced by electrochemical reactions and to reduce the current hysteresis value by improving distribution through increasing a water content inside a cell.

That is, according to the present disclosure, it is possible to prevent a local dry state due to a decrease in water content in a fuel cell and poor water distribution, thereby ameliorate cell internal performance deviation and improving vehicle performance by utilizing maximum performance of the stack.

In addition, according to the present disclosure, durability may be improved, a warranty period of the fuel cell may be extended, and costs due to deterioration of the fuel cell can be reduced by maintaining an appropriate water content inside the fuel cell.

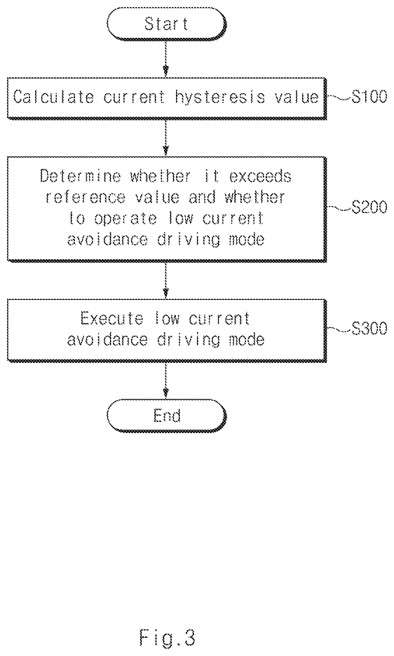

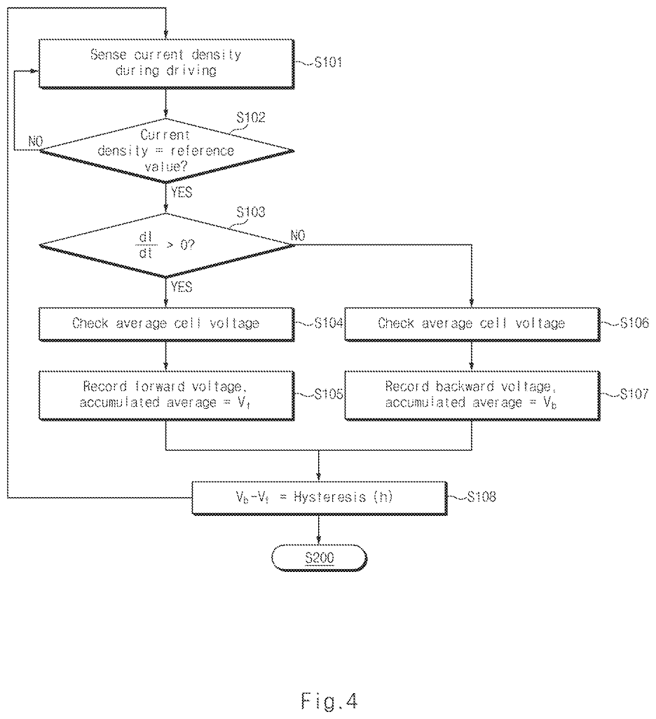

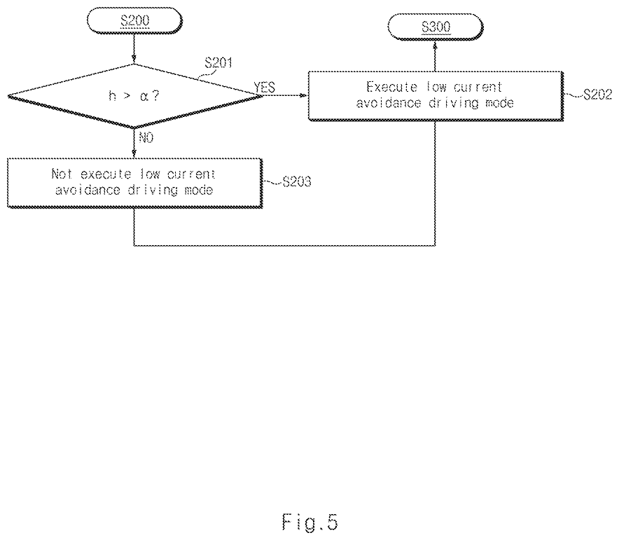

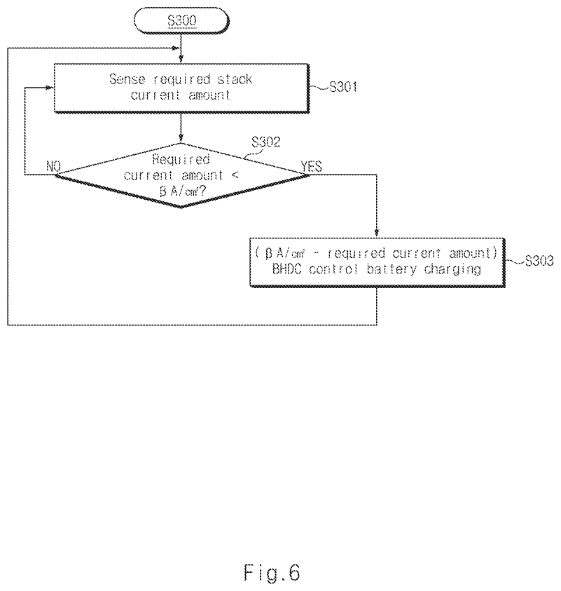

Hereinafter, a current hysteresis reducing method according to an exemplary embodiment of the present disclosure will be described in detail with reference to FIG. 3 to FIG. 6. FIG. 3 illustrates a current hysteresis reducing method according to an exemplary embodiment of the present disclosure. FIG. 4 illustrates a flowchart showing a method for calculating a current hysteresis value according to an embodiment of the present disclosure, FIG. 5 illustrates a flowchart showing a method for determining a current hysteresis value according to an embodiment of the present disclosure, and FIG. 6 illustrates a low current avoidance driving method according to an exemplary embodiment of the present disclosure.

Hereinafter, it is assumed that the current hysteresis reducing apparatus 100 of FIG. 1 performs the processes of FIG. 3 to FIG. 6. In addition, in the description of FIG. 3 to FIG. 6, operations described as being performed by the device may be understood as being controlled by the processor 130 of the current hysteresis reducing apparatus 100.

Referring to FIG. 3, the current hysteresis reducing apparatus 100 derives a hysteresis value at S100.

That is, the current hysteresis reducing apparatus 100 may divide the voltage at a specific current into forward or backward depending on a current change rate with respect to time, and may utilize an average of the divided voltages to calculate a current hysteresis value. The current hysteresis reducing apparatus 100 may calculate the current hysteresis value in real time based on current data and voltage data measured after the vehicle is started. A detailed process of deriving the current hysteresis value of the step S100 will be described in more detail later with reference to FIG. 4.

Next, the current hysteresis reducing apparatus 100 determines whether the calculated current hysteresis value exceeds a predetermined reference value, and determines whether to operate a low current avoidance driving mode depending on a determination result thereof at S200. In this case, the reference value may be different for each fuel cell specification, and may be predetermined according to an experimental value. The current hysteresis reducing apparatus 100 may execute the low current avoidance driving mode when the current hysteresis value exceeds the predetermined reference value. In addition, when the current hysteresis value is continuously compared with the predetermined reference value while the low current avoidance operation mode is being executed, and the current hysteresis value is reduced to be smaller than or equal to the predetermined reference value, operation of the low current avoidance driving mode may be ended. A detailed process of determining whether the low current avoidance driving mode is operated based on whether the current hysteresis value exceeds the reference value in the step S200 will be described in more detail later with reference to FIG. 5.

Then, the current hysteresis reducing apparatus 100 executes low current avoidance driving at S300. That is, the current hysteresis reducing apparatus 100 may utilize the excess of a required current amount of the actual stack current for battery charging through the BHDC, like the conventional BHDC-utilized voltage upper limit control method. A process of executing the low current avoidance driving of the step S300 will be described in more detail later with reference to FIG. 6.

The current hysteresis may vary depending on a driving temperature, a gas humidification state, and a deterioration degree of the electrode, and in all situations, artificial avoidance of low current may affect vehicle fuel efficiency, and accordingly, according to the present disclosure, a hysteresis value is derived under existing voltage upper limit control, the low current avoidance driving mode is executed in a specific situation (when the current hysteresis exceeds the reference value), and the voltage upper limit control is performed again when the current hysteresis is smaller than or equal to the reference value.

Accordingly, according to the present disclosure, when the current hysteresis exceeds the reference value during driving, it is possible to increase a water content and improve water distribution in the fuel cell by changing the existing voltage upper limit control to current density lower limit control and executing the low current avoidance driving, thereby ameliorating performance variation within the cell and preventing electrode degradation.

Referring to FIG. 4, the current hysteresis reducing apparatus 100 monitors a current density sensed during vehicle driving at S101, and determines whether the current density during the vehicle driving is a predetermined reference value at S102. For example, the predetermined threshold is 0.32 A/cm², which may be determined by an existing hysteresis measurement method and a verification test, and may be changed to a range or another value.

When the current density is the predetermined reference value, the current hysteresis reducing apparatus 100 determines whether a current change rate

$$( \frac{d I}{d t} )$$

with respect to time is greater than 0 at S103. Accordingly, the current hysteresis reducing apparatus 100 may determine whether it is a forward situation that is a voltage increasing situation or a backward situation that is a voltage decreasing situation depending on the current change rate with respect to time. That is, the current hysteresis measurement method in the evaluation device may not be applied because a stack generation current may change in real time during actual vehicle driving. Accordingly, the current hysteresis reducing apparatus 100 determines whether a current situation is the forward situation or the backward situation depending on a change in current over time.

That is, when the current change rate with respect to time is greater than 0, the current hysteresis reducing apparatus 100 determines it as the forward situation, checks an average cell voltage at S104, and records and accumulates the average cell voltage based on the current change rate with respect to time, to calculate the accumulated average voltage V_{f} of the forward situation at S105.

On the other hand, when the current change rate with respect to time is 0 or less, the current hysteresis reducing apparatus 100 determines it as the backward situation, checks the average cell voltage at S106, and records and accumulates the average cell voltage based on the current change rate with respect to time, to calculate the accumulated average voltage V_{b} of the backward situation at S107.

The current hysteresis reducing apparatus 100 may reflect a latest state of the fuel cell stack by initializing the accumulated average voltage V_{b} of the backward situation and the accumulated average voltage V_{f} of the forward situation when the vehicle driving is ended (starting OFF) and by performing the above-described steps S101 to S108 to newly record the accumulated average voltage V_{b} of the backward situation and the accumulated average voltage V_{f} of the forward situation when the vehicle driving is started (starting ON).

Thereafter, the current hysteresis reducing apparatus 100 calculates current hysteresis h by subtracting the accumulated average voltage V_{f} of the forward situation from the accumulated average voltage V_{b} of the backward situation at S108. The calculation of current hysteresis may be performed in real time and updated in real time.

Referring to FIG. 5, the current hysteresis reducing apparatus 100 determines whether the current hysteresis h calculated in FIG. 4 exceeds a predetermined reference value α at S201. In this case, the predetermined reference value α varies depending on fuel cell specifications such as components and MEA, and thus it may be set differently for each vehicle type, and may be predetermined depending on an experimental value.

When the current hysteresis h exceeds the predetermined reference value a, the current hysteresis reducing apparatus 100 determines that current hysteresis reduction is necessary, and executes the low current avoidance driving mode at S202.

On the other hand, when the current hysteresis h is smaller than or equal to the predetermined reference value α, the current hysteresis reducing apparatus 100 determines that the current hysteresis reduction is not necessary, and does not execute the low current driving mode at S203, and switches to the voltage upper limit control.

In this case, the current hysteresis reducing apparatus 100 may determine whether low current avoidance driving is necessary by comparing the current hysteresis calculated in real time with a reference value in real time.

Referring to FIG. 6, the current hysteresis reducing apparatus 100 senses a required stack current amount when it is determined to execute the low current avoidance driving mode in FIG. 5 at S301. In this case, a separate sensor may be provided for sensing the required stack current amount.

The current hysteresis reducing apparatus 100 determines whether the required stack current amount is smaller than a predetermined reference value β at S302. In this case, the predetermined reference value β is a lower limit current density reference value, which may vary depending on specifications and may be set by an experimental value.

When the required stack current amount is smaller than the predetermined reference value β, the current hysteresis reducing apparatus 100 may utilize the excess of the required current amount for battery charging through the BHDC 400 in a same manner as the voltage upper limit control method after generating a current as much as the predetermined reference value β, at S303.

When the required stack current amount is equal to or greater than the predetermined reference value β, the current hysteresis reducing apparatus 100 senses the required stack current amount at S301.

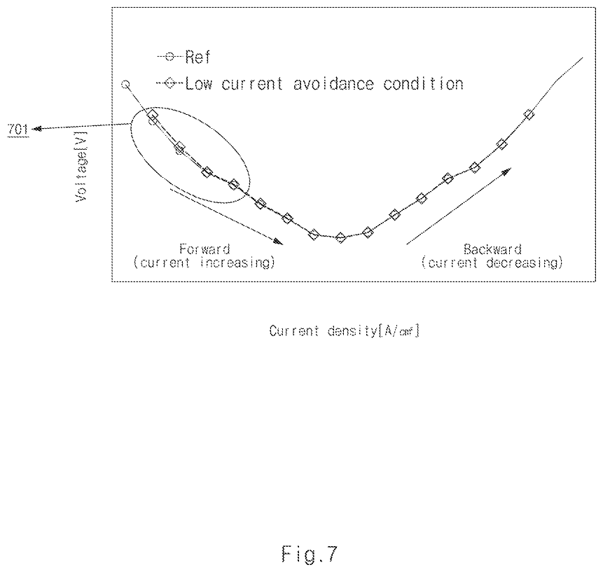

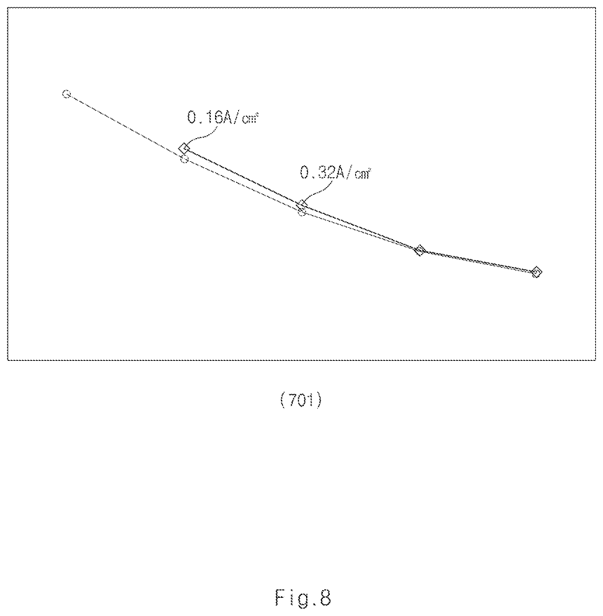

FIG. 7 illustrates a current hysteresis measurement graph according to an exemplary embodiment of the present disclosure, and FIG. 8 illustrates a comparison of forward section performance in FIG. 7.

Referring to FIG. 7, performance deteriorates compared to a current decreasing area (Backward), thereby generating current hysteresis in a current increasing area (Forward) 701 due to a small amount of water in the low-current area.

It can be seen that a forward performance difference occurs due to a difference in cell water contents in the low-current area (when avoiding a low current, the forward performance increases by preventing cell drying due to a decrease in water content), and a current hysteresis value is improved.

That is, referring to FIG. 8, it can be seen that the water content in the cell is increased in the low current avoidance driving mode, to increase the forward performance and to reduce the current hysteresis.

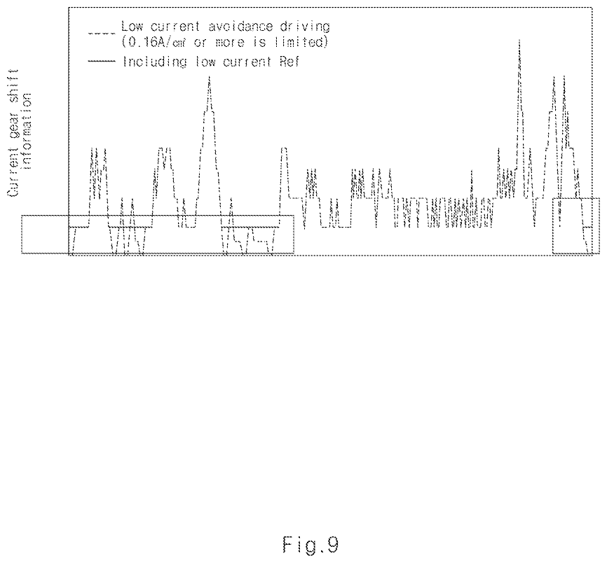

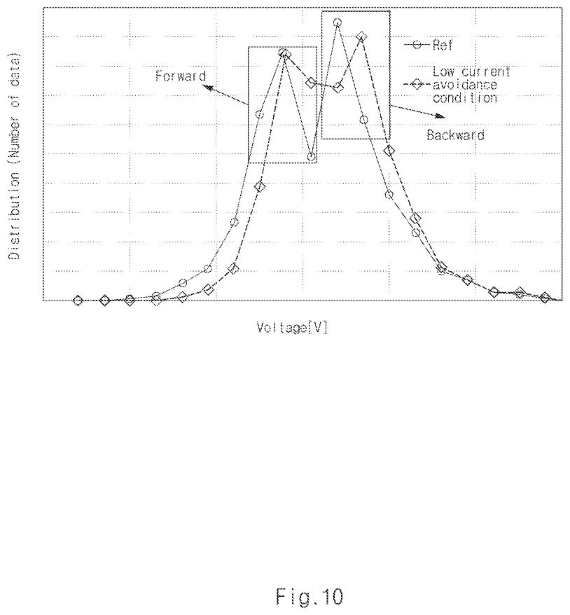

FIG. 9 illustrates a simulated current profile during actual driving of a vehicle according to an exemplary embodiment of the present disclosure, and FIG. 10 illustrates voltage distribution during simulation of actual driving of a vehicle according to an exemplary embodiment of the present disclosure.

The existing current hysteresis measurement method is an artificial current cycle measurement, which is different from the actual driving profile. Accordingly, in the present disclosure, it is divided into the forward situation and the backward situation depending on the current change rate using a voltage at a predetermined reference value (e.g., @ 0.32 A/cm²).

That is, as illustrated in FIG. 10, it may be checked on forward and backward voltage distribution graphs. Accordingly, according to the present disclosure, it is possible to reduce the current hysteresis during driving depending on a fuel cell specification by avoiding the low current. Thus, it is possible to increase the water content and ameliorate a water distribution deviation in the fuel cell, thereby preventing local drying of the cell, and improving performance and durability of a hydrogen fuel cell vehicle.

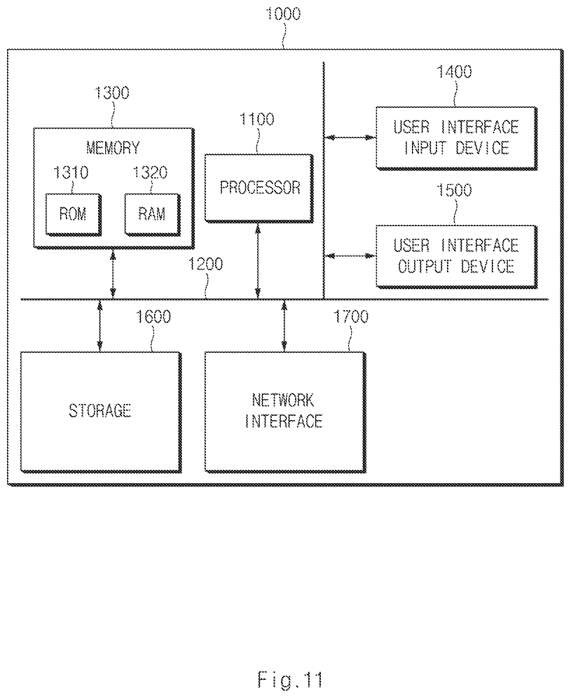

FIG. 11 illustrates a computing system according to an exemplary embodiment of the present disclosure.

Referring to FIG. 11, the computing system 1000 includes at least one processor 1100 connected through a bus 1200, a memory 1300, a user interface input device 1400, a user interface output device 1500, and a storage 1600, and a network interface 1700.

The processor 1100 may be a central processing unit (CPU) or a semiconductor device that performs processing on commands stored in the memory 1300 and/or the storage 1600. The memory 1300 and the storage 1600 may include various types of volatile or nonvolatile storage media. For example, the memory 1300 may include a read only memory (ROM) 1310 and a random access memory (RAM) 1320.

Accordingly, steps of a method or algorithm described in connection with the exemplary embodiments disclosed herein may be directly implemented by hardware, a software module, or a combination of the two, executed by the processor 1100. The software module may reside in a storage medium (i.e., the memory 1300 and/or the storage 1600) such as a RAM memory, a flash memory, a ROM memory, an EPROM memory, an EEPROM memory, a register, a hard disk, a removable disk, and a CD-ROM.

An exemplary storage medium is coupled to the processor 1100, which can read information from and write information to the storage medium. Alternatively, the storage medium may be integrated with the processor 1100. The processor and the storage medium may reside within an application specific integrated circuit (ASIC). The ASIC may reside within a user terminal. Alternatively, the processor and the storage medium may reside as separate components within the user terminal.

The above description is merely illustrative of the technical idea of the present disclosure, and those skilled in the art to which the present disclosure pertains may make various modifications and variations without departing from the essential characteristics of the present disclosure.

Therefore, the exemplary embodiments disclosed in the present disclosure are not intended to limit the technical ideas of the present disclosure, but to explain them, and the scope of the technical ideas of the present disclosure is not limited by these exemplary embodiments. The protection range of the present disclosure should be interpreted by the claims below, and all technical ideas within the equivalent range should be interpreted as being included in the scope of the present disclosure.

1. A current hysteresis reducing apparatus comprising:
a processor configured to calculate a current hysteresis value of a fuel cell, to determine whether to operate a low current avoidance driving mode by using the current hysteresis value, and to enter the low current avoidance driving mode to avoid a low-current driving area; and
a storage configured to store data and algorithms driven by the processor.

2. The current hysteresis reducing apparatus of claim 1, wherein the processor, when entering the low current avoidance driving mode, is configured to avoid a low-current driving area where there is little water produced by electrochemical reactions by generating a stack current to be greater than or equal to a reference value.

3. The current hysteresis reducing apparatus of claim 1, wherein the processor is configured to control a stack current to be generated to be greater than or equal to lower limit current density when entering the low current avoidance driving mode.

4. The current hysteresis reducing apparatus of claim 3, wherein the processor, when entering the low current avoidance driving mode, is configured to use an excess of a required current amount of the stack current for charging a battery through bidirectional high voltage DC/DC converter (BHDC) in a voltage upper limit control method.

5. The current hysteresis reducing apparatus of claim 1, wherein the processor is configured to determine current density sensed while driving a vehicle based on a predetermined reference value.

6. The current hysteresis reducing apparatus of claim 5, wherein the processor is configured to distinguish a current increasing situation and a current decreasing situation by using an amount of change in current with time when the current density is the predetermined reference value.

7. The current hysteresis reducing apparatus of claim 6, wherein the processor is configured to calculate an accumulated average voltage by accumulating an average cell voltage in the current increasing situation, and
configured to calculate the accumulated average voltage by accumulating an average cell voltage in the current decreasing situation.

8. The current hysteresis reducing apparatus of claim 7, wherein the processor is configured to calculate the current hysteresis value by using the accumulated average voltage in the current increasing situation and the accumulated average voltage in the current decreasing situation.

9. The current hysteresis reducing apparatus of claim 8, wherein the processor is configured to calculate the current hysteresis value by subtracting the accumulated average voltage in the current increasing condition from the accumulated average voltage in the current decreasing condition.

10. The current hysteresis reducing apparatus of claim 9, wherein the processor is configured to initialize the accumulated average voltage in the current decreasing situation and the accumulated average voltage in the current increasing situation when the vehicle ends driving, and to calculate the current hysteresis value by re-calculating the accumulated average voltage in the current decreasing situation and the accumulated average voltage in the current increasing situation when the vehicle starts driving.

11. The current hysteresis reducing apparatus of claim 1, wherein the processor is configured to compare the current hysteresis value with a predetermined reference value, and when the current hysteresis value exceeds the predetermined reference value, determines a state requiring reduction of current hysteresis.

12. The current hysteresis reducing apparatus of claim 1, wherein the processor, when the current hysteresis value exceeds the predetermined reference value, is configured to enter the low current avoidance driving mode.

13. The current hysteresis reducing apparatus of claim 1, wherein the processor,
when the current hysteresis value exceeds the predetermined reference value, is configured to change from a voltage upper limit control method to a current lower limit control method to perform it, and
when the current hysteresis value is smaller than or equal to a predetermined reference value, configured to change from the current lower limit control method to the voltage upper limit control method.

14. A current hysteresis reducing method comprising:
calculating, by a processor, a current hysteresis value of a fuel cell;
determining whether to operate a low current avoidance driving mode by using the current hysteresis value; and
entering the low current avoidance driving mode to avoid a low-current driving area.

15. The current hysteresis reducing method of claim 14, wherein the entering of the low current avoidance driving mode includes,
when entering the low current avoidance driving mode, avoiding a low-current driving area where there is little water produced by electrochemical reactions by generating a stack current to be greater than or equal to a reference value.

16. The current hysteresis reducing method of claim 14, wherein the entering of the low current avoidance driving mode includes controlling a stack current to be generated to be greater than or equal to lower limit current density when entering the low current avoidance driving mode.

17. The current hysteresis reducing method of claim 16, wherein the entering of the low current avoidance driving mode includes, when entering the low current avoidance driving mode, using an excess of a required current amount of the stack current for charging a battery through bidirectional high voltage DC/DC converter (BHDC) in a voltage upper limit control method.

18. The current hysteresis reducing method of claim 14, wherein the calculating of the current hysteresis value of the fuel cell includes:
determining current density sensed while driving a vehicle based on a predetermined reference value; and
distinguishing a current increasing situation and a current decreasing situation by using an amount of change in current with time when the current density is the predetermined reference value.

19. The current hysteresis reducing method of claim 18, wherein the calculating of the current hysteresis value of the fuel cell includes:
calculating an accumulated average voltage by accumulating an average cell voltage in the current increasing situation; and
calculating an accumulated average voltage by accumulating an average cell voltage in the current decreasing situation.

20. The current hysteresis reducing method of claim 19, wherein the calculating of the current hysteresis value of the fuel cell includes:
calculating the current hysteresis value by using the accumulated average voltage in the current increasing situation and the accumulated average voltage in the current decreasing situation.
